(19) United States
(12) Patent Application Publication
(10) Pub. No.: US 2008/0190656 A1
(43) Pub. Date: Aug. 14, 2008

(54) Trimming Of Embedded Passive Components Using Pulsed Heating

(75) Inventors: David Cheeke, Victoria (CA); Leslie M. Landsberger, Westmount (CA)

Correspondence Address: OGILVY RENAULT LLP, 1981 MCGILL COLLEGE AVENUE, SUITE 1600, MONTREAL, QC, H3A2Y3, omitted

(73) Assignee: MICROBRIDGE TECHNOLOGIES INC., Montreal Quebec (CA)

(21) Appl. No.: 11/579,727

(22) PCT Filed: May 6, 2005
(86) PCT No.: PCT/CA2005/000698

§ 371 Date: Nov. 2, 2007

Related U.S. Application Data
(60) Provisional application No. 60/568,250, filed on May 6, 2004.

(51) Int. Cl. H05K 1/02; H05K 3/30

(52) U.S. Cl. 174/260; 174/250; 29/846

(57) ABSTRACT

There is described a printed circuit board with a thermally trimmable component embedded therein. A layer of refractory insulating material is provided to provide mechanical support and chemical passivation for the thermally trimmable component. The component is trimmed by applying a sequence of heat pulses the a heating element, which could be the component itself or a separate element. A cavity may be burned in the substrate to provide thermal isolation for the thermally trimmable component.

### TECHNICAL FIELD

The present invention relates to the field of passive electrical components embedded in printed circuit boards for all types of applications.

### BACKGROUND OF THE INVENTION

Printed circuit boards (PCBs) generally consist of a multi-layered structure of patterned conducting lines embedded within electrically-insulating dielectrics. Integrated circuits and passive components are typically mounted on the surface of a printed circuit board, with specific interconnections (between mounted components and from mounted components to external connections), realized by the conductive lines within the body of the PCB. Embedded passives are passive circuit elements (resistances, capacitances, or inductances), which are embedded into the PCB substrate material itself so that the passive component becomes a part of the substrate body.

There are several reasons for the high level of interest in embedded passives, as compared to typical PCB technology with surface-mounted passive devices. The stray inductance associated with the resistor element is reduced by the use of shorter, direct leads (vias within the PCB layered structure). This allows the construction of faster PCBs which can be used in the range 1-10 GHz. Moving passives from the surface of the PCB to an embedded configuration results in a much smaller surface area consumed by the passive components. This also means that different components can be put closer together, which also allows an increase in the speed. The embedded configuration leads to a reduction, and in some cases the elimination, of solder needed for surface mounted components. There is also a reduction of circuitry needed to route signals to the periphery of the board. Finally, a PCB for embedded passives should be ultimately (in high volume), less expensive than surface mount technology for equivalent functionality, if the full savings in cost of assembly are taken into account.

In terms of the adjustability of embedded passives, presently standard mechanical potentiometers can be surface mounted on the board, but this defeats the purpose of surface area reduction by the use of embedded passives. Laser trimming can be used during fabrication. It has been shown that, by laser trimming, it is possible to obtain tolerances on the order of 1% for embedded passives made by polymer thick films, metal thin films and ceramics. In this case one must start with a resistance value 15 to 20% larger than the target value.

Despite its successes and its promise there are several features of the embedded passive technology which are holding back its widespread acceptance. Lack of infrastructure and of suitable CAD tools are two major obstacles to growth. A third one is the lack of a satisfactory trimming solution. The untrimmed tolerances are generally too high for many applications; these can be as high as 40%. Adjustability is presently done by laser trimming, which is a heavy investment in capital equipment and space. Another concern is that such laser trimming must be done before packaging, and thus field trimming is not possible. A further limitation is that so far it has not been possible to do better than 1% precision. Furthermore the temperature variation of embedded resistors can be very significant, especially with aging and/or at high temperature.

Accordingly, there is a real need for improvements to embedded passive technology in the area of trimming. It would be desirable that this could be done after packaging and/or in the field so as to compensate the effects of ageing.

### SUMMARY OF THE INVENTION

It is an object of the present invention to provide a new and useful method and apparatus.

In accordance with a first aspect of the present invention, there is provided a printed circuit board having at least one embedded thermally trimmable component comprising: a substrate layer to provide physical support for the board; a refractory insulating material on the substrate layer to provide at least one of mechanical support and chemical passivation for the thermally trimmable component; a layer of thermally mutable material on the insulator material to form the thermally trimmable component; and a conducting layer on the thermally mutable material to serve for electrical connections of the printed circuit board.

Preferably, the support medium is glass or silicon nitride. Also preferably, the conducting layer is copper foil, the thermally mutable material is polysilicon, and the component is a resistor.

In accordance with a second broad aspect of the present invention, there is provided a method of trimming a thermally trimmable component embedded into a printed circuit board, the method comprising: embedding at least one layer of thermally mutable material into the board; forming the component from the thermally mutable material; populating at least a portion of the board with additional circuit components and connecting the thermally trimmable component to the additional circuit components; and subjecting the thermally trimmable component to a series of heat pulses to trim the thermally trimmable component.

Preferably, the layer of thermally mutable material is used to form a functional resistor and a heating resistor, and the trimming is done by applying a sequence of heat pulses to the heating resistor to subject the functional resistor to thermal heat.

In accordance with a third broad aspect of the present invention, there is provided a method for producing a printed circuit board with at least one embedded thermally trimmable component, the method comprising: embedding at least one layer of thermally mutable material into the board and forming the thermally trimmable component from the thermally mutable material; providing a heating element capable of heating itself and its immediate surroundings; passing an electric current through the heating element to generate a heat source to burn away a portion of a material close to the thermally mutable component at least one of above and below the thermally mutable component to provide a cavity for thermal isolation of the thermally trimmable component.

The printed circuit board may be embedded with a layer of refractory material between a layer of thermally mutable material and a substrate. The layer of refractory material may provide mechanical support or chemical passivation for the thermally mutable material, but it will not stop heat from affecting the substrate. Therefore, a cavity may be formed in the substrate beneath the layer of refractory material.

Additionally, other PCB layers may be superimposed onto the thermally mutable material and a cavity may be formed above the thermally trimmable component where the conducting layer has been removed into the subsequent layer, which could be another substrate layer. These cavities can be formed above the thermally trimmable component, below it, or both, depending on the properties of the surrounding layers.

In accordance with a fourth broad aspect of the present invention, there is provided a system for producing a printed circuit board with at least one embedded thermally trimmable component, the system comprising: a stack of layers comprising at least a substrate, the thermally trimmable component, a heating element and a conducting layer for electrical connections of the printed circuit board; and heating circuitry for passing an electric current through the heating element to generate a heat source to burn away a portion of a material at least one of above and below the thermally mutable component to provide a cavity for thermal isolation of the thermally trimmable component.

The heating element may be, for example, the thermally trimmable component itself, a heating resistor formed from the same thermally mutable material as the thermally trimmable component, or a heating resistor formed from a separate layer placed above or below the thermally mutable material.

The cavity may be burned above, below, or above and below the thermally trimmable component in substrate layers. The substrate layers may be separated from the thermally trimmable component by a layer of refractory material to provide mechanical support and/or chemical passivation for the thermally mutable material, but it will not stop heat from affecting the substrate.

### BRIEF DESCRIPTION OF THE DRAWINGS

Further features and advantages of the present invention will become apparent from the following detailed description, taken in combination with the appended drawings, in which:

FIG. 1 is a prior art diagram showing a resistor laminate;

FIG. 2 is a sectional view showing the component laminate in accordance with the present invention;

FIG. 3 is a perspective view showing the layout of the polysilicon heating and functional resistors to be patterned onto the structure of FIG. 2;

FIG. 4 is a is a sectional view of the resistor embedded in the PCB with electrical connections made by vertical vias in the material;

FIG. 5 is a sectional view of the multilayer structure formed by sputtering layers of nitride, polysilicon and copper on to a plastic substrate;

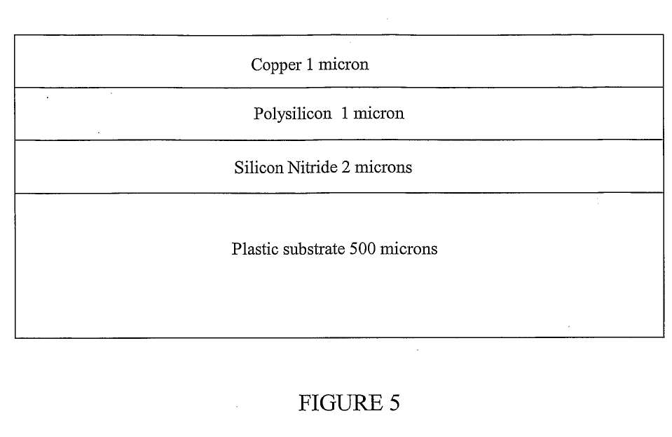

FIG. 6 is a sectional view of how a cavity could be burned in the component laminate before attaching it to other layers of the PCB; and

FIG. 7 is a sectional view of how a cavity could be burned in both the substrate of the laminate and the adjoining PCB layer for the case where the component laminate is fully embedded in the PCB.

It will be noted that throughout the appended drawings, like features are identified by like reference numerals.

### DETAILED DESCRIPTION OF THE PREFERRED EMBODIMENT

The basic principles of trimmable resistors have been described in PCT publication WO2003/023794, which is hereby incorporated by reference. The algorithms for trimming have been described in PCT applications PCT/CA2004/000397 and PCT/CA2004/000398, also hereby incorporated by reference. A heating resistor and a functional resistor both made out of polysilicon are placed in close proximity on a self-supporting, thermally isolated microstructure. Polysilicon belongs to the class of thermally mutable materials, whereby an increase in temperature to sufficiently high values leads to a change in the internal structure of the material, giving rise to a change in room-temperature electrical resistance, as well as potentially a change in temperature coefficient of resistance. Pulse heating of the heating resistor by a few tens of mW is sufficient to bring the temperature of the structure up to 600° C. to 1000° C., in a time on the order of 1 ms to 10 ms, due to the small thermal mass and high thermal isolation of the structure. This process allows very rapid thermal annealing of the polysilicon film to take place, and the associated changes in grain structure, grain boundaries, and dopant distribution with respect to the grain boundaries, lead to changes in resistance of the film. Furthermore, it has been shown that if an appropriate algorithm is used to control the amplitude, width and sequencing of the applied pulses, the steady state resistance can be adjusted either up or down, within a certain range, to a new stable value. Bidirectional resistance trimming takes a few seconds in an automated mode.

The principle of trimmable resistors can also be modified to trim the temperature coefficient of resistance (TCR) of a single resistor and the relative TCR (RTCR) of a pair of resistors The RTCR of a pair of trimmable resistors can be varied over a range of a few tens of ppm/K in a time on the order of a few tens of seconds.

The fundamental principle involved in the operation of trimmable resistors is that the functional and heating resistors must each have small thermal mass and be very well thermally isolated, both conditions being necessary in order to attain very rapid heating of the resistors to a temperature sufficiently high, approximately 600° C. or more, to allow in situ localized thermal annealing to take place. In the trimmable resistor these two conditions are fulfilled by the use of a thermally isolated microstructure, self supported above or within a cavity. The structure is then part of a silicon integrated circuit, where there may be other circuitry in close proximity to the microstructure. Due to the thermal isolation, this adjacent circuitry remains unaffected by the heating of the microstructure.

Thermal isolation can be provided in several different ways, and not uniquely by suspending the heater and trimmable resistor in a micro-machined silicon cavity. With the structure suspended in such a micro-machined cavity, the heat is dissipated by thermal radiation from the structure, by thermal conduction through the air in the cavity and via the supporting base of the structure, including the electrical connecting leads. It has been estimated that the dominant heat loss mechanism is by thermal conduction through the supporting arms of the microstructure (as opposed to by thermal radiation, or by thermal conduction through the surrounding gas). If a highly insulating material with a low thermal conductivity approaching that of air were applied effectively, it could be used to replace the air in the cavity, leading to an alternative technology.

Polymeric materials used in the construction of PCBs all have very low thermal conductivities of roughly the same value. For example, Kapton™, a common material used for this purpose, has a thermal conductivity of 160 mW/m*K, about six times higher than that of air, which is 25 mW/m*K. The value for Kapton™ is relatively close to that of air compared to other materials. For example, for comparison purposes, glass (another good insulator), has a thermal conductivity of 930 mW/m*K and stainless steel has a thermal conductivity of 16 W/m*W, orders of magnitude higher. The value for Kapton™ is sufficiently close to that of air that if the heating and functional resistors were surrounded by Kapton™ instead of air they could be heated up to 600° C.-1000° C. by application of a sufficient, but not excessive, amount of heat.

A preferred embodiment of the present invention is to embed the polysilicon functional and heating resistors in the layers of a PCB using embedded passive technology, so that the trimmable resistor becomes an integral part of the PCB. The polysilicon is deposited by sputtering method, on copper foil which may be about 10 microns thick. The polysilicon is then coated with a thin layer (1 or 2 microns) of insulator such as glass or Silicon Nitride, (deposited sputtering, or spin-on methods) which also acts as a support medium, able to mechanically support the resistor in case the polymer material is damaged during heating associated with the trimming process. These layers are then bonded to an appropriate thickness of Kapton™ to form a laminate which forms the basic building block for the embedded passive structure. Layout of the heating and functional resistors is then carried out by standard CAD techniques, followed by the appropriate pattern (e.g. photolithography) and etch steps to form the final device. Any time after the full board has been assembled trimming is carried out by applying a series of pulses to the heating resistor, as described in WO2003/023794, PCT/CA2004/000397, and PCT/CA2004/000398.

In another embodiment of the present invention, the polysilicon is replaced by any other thermally mutable material such as SiGe, SiCr, or various metallic alloys. The trimming procedure is adapted to take into account the different temperatures and pulse sequencing techniques required by each different material.

In another embodiment of the present invention, a layer of silicon nitride is sputtered onto a thin plastic substrate, as above for reasons of structural support after trimming. A layer of thermally mutable material is then sputtered onto the nitrided plastic as is done in the fabrication of poly-Si thin-film transistor (TFT)-based liquid crystal displays (LCDs). A layer of copper to ultimately serve for the electrical connections is then sputtered onto the thermally mutable material.

As in the preferred embodiment the multilayer stack is then bonded to bulk Kapton™ (or other suitable electrical and thermal insulator) having suitable thickness; the resulting unit is then ready for embedding in the PCB.

Note that the glass or nitride layer may or may not be necessary as a mechanical support, and may or may not be needed as a barrier against chemical reaction, depending on a variety of factors (such as the material and composition of the substrate material and PCB material to be laminated on top of it, the thickness of the thermally-trimmable material and chemical reactivity of its surfaces). Similarly, another refractory support or barrier layer may be needed on the other side of the thermally-trimmable layer, which may eventually be laminated with another PCB substrate. In general, the support/barrier layer may be needed or not needed on one or both sides of the thermally trimmable layer. In this text, we have described the case of glass/nitride on one side of the thermally-trimmable resistive layer.

Regarding the materials and technologies typically used in embedded passive capacitors and resistors, there are three main categories:

(1) Materials deposited, plated or laminated on copper foil: Glass-reinforced epoxy (for capacitors—Sanmina); Ceramic-filled polyimide (for capacitors—DuPont); Resistor materials, for example Pt (Shipley-Ronal), and NiP (Ohmega-Ply).

(2) Materials in paste form which are applied to copper foil and cured by the PCB manufacturer.

(3) Plating onto copper foil, done by the PCB manufacturer, such as NiP-based plated resistors (MacDermid)

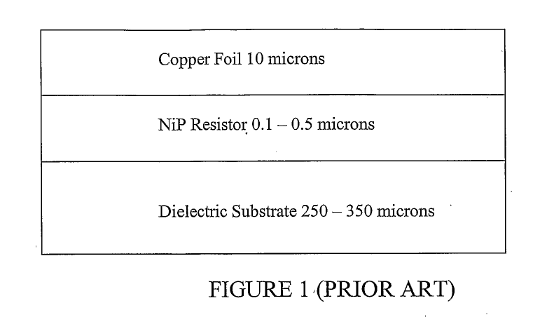

As an example, we will focus on the Ohmega-Ply technology, as outlined in the Design Guide by Ohmega Technologies, Inc by Dong Nong, hereby incorporated by reference. The structure can be seen in FIG. 1. The principal steps involved in this technology for the fabrication of an embedded passive resistor are as follows.

The typical process for this traditional version of embedded passive begins with a copper foil, having typical thickness 10 microns or more. Next, one deposits the resistive film of NiP, about 0.1-0.5 microns thick. The deposition can be done by plating, evaporation, sputtering or any other suitable method. Next, one binds (by lamination of films), the coated copper foil together with a dielectric material to form a laminate structure typically 250-350 microns thick. The dielectric material may be any one of a number of polymer based materials, such as Kapton or polyimide. Next, one chooses the desired layout for the resistor, such as in a linear or serpentine configuration. Each square of resistor trace would have a resistance (for example, in the range 25 ohms per square to 250 ohms per square, depending on the parameters of the NiP layer, such as thickness). Typically a resistor trace would comprise about 10 to 100 squares. Next, one chooses the circuit-connecting conductor width, usually in the range 250-500 microns. Next, multiple photolithographic print and etch processes are executed, to pattern the NiP resistors and copper connections. Eight sequential steps are described by Ohmega-Ply.

The heat dissipation mechanisms in the PCB structure are very relevant to the present invention. They are determined by: Size of the resistor; Thickness and material characteristics of the interconnect material (in this case copper); Circuit configuration (clad or unclad); Ambient temperature; Thermal conductivity of substrate; Additional cooling of the substrate.

The above parameters determine the temperature rise of the resistor for a given dissipated power density. Infra-red measurements have shown that for the smallest Ohmega-Ply resistors studied (0.031×0.031 in. squares, area about 0.7 mm²) a temperature rise of 160° C. was obtained for a dissipated power of about 120 mW. A linear variation of temperature rise with dissipated power was observed up to that temperature.

The resistive stability of Ohmega-Ply material with temperature and time was measured over the range 45-140° C. for thousands of hours. For example, after 10000 hours the resistance changes for different temperatures were: <0.1% at 45° C.; 1.75% at 70° C.; 2.2% at 110° C.; 4.5% at 140° C.

A significant amount of environmental reliability test data for Ohmega-Ply NiP resistors is available. Its reliability in severe environmental conditions has also been demonstrated by over 25 years in numerous applications.

Gould Electronics, Inc. conducted a series of experiments where the fabrication tolerances were carefully controlled. For untrimmed passive NiCr resistors made by a similar technology to the Ohmega-Ply, the observed tolerances for untrimmed embedded passive resistors was: +/−33% for 125-micron wide resistor lines, +/−20% for 250-micron lines and +/−6% for 1 mm. lines. For small (5 or 10 mils) resistors, material conformity and etching control were found to be the dominant parameters. For larger resistors the material tolerance was found to be the main factor. Tolerances better than the above values could only be obtained by laser trimming. For all embedded passive technologies, the best available untrimmed tolerances have been estimated to be in the range 8-16%.

An example of laser trimming of embedded passives in the final stages of fabrication is given in U.S. Pat. No. 6,677,827 for the case of temperature controlled crystal oscillators (TXCOs).

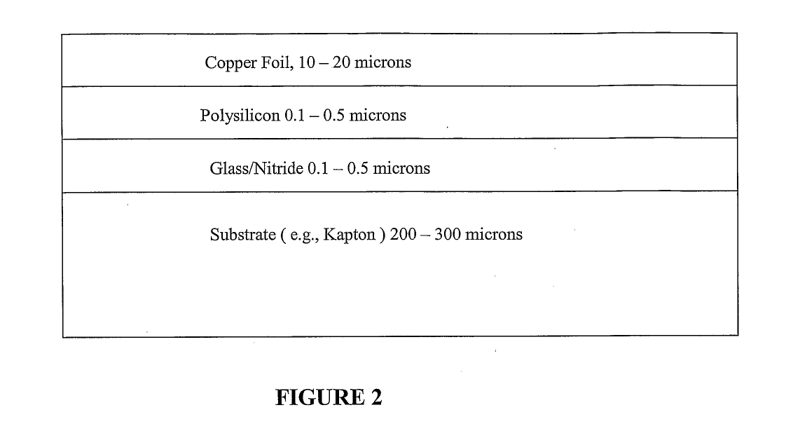

Referring to FIG. 2, the starting material is a copper foil of thickness about 10 micrometers or more. The surface of the copper will be treated as necessary according to standard techniques to improve the adhesion of films deposited onto it. For example, as shown in Ni film U.S. Pat. No. 6,610,417 it has been found for this application that a thin sub-micron-thick film of Nickel, deposited by thermal evaporation or sputtering by well known techniques, considerably improves the adhesion of thin metallic films deposited on the copper.

Poly-Si films on silicon are usually made using low pressure chemical vapor deposition (LPCVD). While this procedure is preferred for dielectric substrates in integrated circuit fabrication it may be inappropriate to the present case of a metallic substrate, due to the corrosive properties of the ambient gas usually employed (silane), which is even more corrosive at the very high temperatures used in LPCVD (600-700° C.). In the case of metallic substrates, sputtering in any of its standard forms (DC, RF or magnetron), is preferable, as it allows for the use of a wide range of substrates and the use of much lower temperatures (typically 400° C. down to room temperature).

There are several other advantages in the sputtering method proposed below and some are as follows. Low hydrogen content (advantageous for the subsequent annealing step used to transform amorphous silicon to poly-Si). The process is easily scaleable to larger substrate areas, so that large scale manufacturing would be feasible. Glass or nitride films can be made in the same sputtering system by a simple modification of the gaseous components used. A doped silicon target can be used to produce a lightly doped, highly resistive sputtered silicon film. This is very convenient, as it combines together the deposition and doping steps. The as-deposited crystallinity is high (5%-60%) (Ross, Young, The Display search Monitor of America, Aug. 15, 2001, page 11), which facilitates subsequent annealing of the amorphous silicon into fully polycrystalline form. Improved properties include high, uniform electrical parameters, high density and excellent film thickness uniformity.

For the fabrication process, DC, RF or magnetron sputtering can be used. For illustrative purposes the case of DC magnetron sputtering will be considered. A silicon target, lightly doped with the dopant concentration needed to produce the desired value of resistivity will be used. A vertical deposition chamber architecture is proposed; this is known to effectively eliminate silicon particle formation, which is known otherwise to be a serious problem (T. Voutsas et al, White paper of Sharp laboratories of America, May 2001). Alternatively, RF sputtering could be used if particle formation becomes a problem. The substrate is a thin copper foil about ten microns thick held in a mechanical support made of, e.g. stainless steel. The substrate temperature is not critical, although a higher value (300-400° C.) will give a better film quality. Following (U.S. Pat. No. 6,429,097) a gaseous sputtering mixture will consist of two gases, wherein the first gas is helium and the second gas is one of neon, argon, krypton, xenon and radon. For the following analysis, consider the case of Argon, since it is the most standard and well known gas used in sputtering. In this way mixtures of He/Ar may be used to produce a-Si (partly amorphous silicon films produced by sputtering), additions of O₂/H₂ to produce SiOₓ films and N₂/H₂ to produce SiNₓ films. A uniform gas flow with the Ar/He mixture in the range 3% to 10% Ar in Helium gas has found to be optimal, in the pressure range 1-15 torr for the mixture (U.S. Pat. No. 6,429,097). A sputtering power of about 5 kW has been found to give a deposition rate of 60-120 nm per minute.

Under the deposition conditions described below it is known that the poly film is partly polycrystalline and partly amorphous in the form a-Si. The film can be transformed into 100% polycrystalline material by high temperature and/or long annealing times (Ross, Young, The Display search Monitor of America, Aug. 15, 2001, page 11). Alternatively, excimer laser annealing (ELA) to make a fully polycrystalline film produces excellent results. It is shown in (Ross, Young, The Display search Monitor of America, Aug. 15, 2001, page 11) that the crystallinity of the film can be determined quantitively by Raman scattering. ELA has the further advantage that it reduces the Ar content in the film (U.S. Pat. No. 6,429,097).

In the proposed fabrication sequence a film of a-poly about 1 micron thick will be first deposited on the copper. Using the above procedure, a mixture of N₂/H₂ will be added to the sputtering gas to lead to the deposition a film of nitride several microns thick on the poly to provide mechanical support to the structure during the trimming and post-trimming operations. The essential property of the nitride is, that it be resistant to all process operations and that it be sufficiently strong mechanically to support the polysilicon film should the latter become detached from the matrix. It will be realized by those skilled in the art that nitride of good, normal quality satisfies these requirements. The value of the thermal conductivity of the nitride is of no consequence as it is very thin. The layered structure thus formed is bonded by standard techniques to the substrate material which may be several hundreds of microns thick. The substrate material may be constituted of Epoxy Polyimide, Polyimide/Quartz, RT/duroid, R/flex, Kapton™ or any other low conductivity polymeric material. The resulting laminate forms the basic unit from which the resistor and circuit leads will be fabricated, the whole then being ready for embedding as a layer in the PCB.

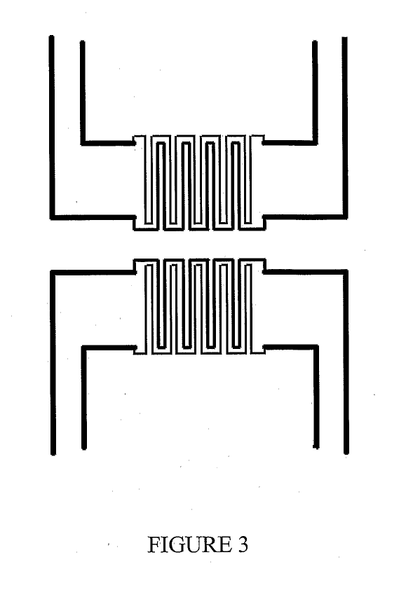

FIG. 3 is a perspective view showing an example layout of the polysilicon heating and functional resistors to be patterned onto the structure of FIG. 2.

Work on the trimmable resistor has shown that polysilicon typically used in the industry has a sheet resistance in the range of 10-300 Ohms per square. The resistance of a square is independent of its absolute size and is determined only by the resistivity of the material at a given thickness. Since the Ohmega-ply material has the same order of magnitude sheet resistance, the global layout and dimensions normally used for it can be directly adapted to this case. All things being equal, the smallest practical line widths (of the order of 100 micrometers or less) for this technology will be used in order to minimize the absolute value of the dissipated power necessary for trimming. Since typical resistance values that are required are of the order of 5 K ohms, a serpentine configuration will be used. It is known from the work of Ohmega-ply that a corner square for the serpentine configuration has an equivalent electrical resistance of 1.56 squares. Alternatively copper shorting bars have been used for the corner squares. In any case, about 50 squares are needed to produce a resistor in the range of 5 K ohms. As for the Trimmable resistor, the heating resistance will closely track the form and position of the functional resistance to maximize the heat transfer between the two. The layout of the resistors may also be optimized to obtain a uniform temperature distribution in the functional resistor during heating. A patterning mask will be made of this layout using standard techniques.

The process steps required to fabricate the heating and functional resistors corresponding to the layout of FIG. 3 on the laminated structure shown in FIG. 2 are known in the art.

An example of the process steps to fabricate the resistor would be a modification of those used in the Ohmega-ply fabrication process, mainly to take into account the existence of the glass or nitride layer and the different resistive material that is used. These steps can be summarized as follows;
(1) Begin with uniform copper foil.
(2) Deposit polysilicon by sputtering as above.
(3) Anneal by ELA to convert the film to 100% poly.
(4) Deposit nitride layer by sputtering as above.
(5) Laminate the multi layer system thus formed to a dielectric substrate of the type described.
(6) Prepare of the surface of the laminate copper side in accordance with the photoresist manufacturer specifications.
(7) Apply a layer of photoresist to the copper surface following the manufacturer's specifications.
(8) Use prescribed exposure conditions.
(9) Develop photoresist.
(10) Check developed images for correct geometrical and physical properties.
11) Etch unwanted copper using any appropriate etchant (selective to copper not photoresist or polysilicon).
(12) Etch polysilicon with appropriate etch technique (selective to polysilicon, not copper).
(13) Strip the photoresist.
(14) Use an oxide treatment on the copper surface to prepare it subsequent for bonding.
(15) Apply photoresist
(16) Print and develop conductor protection pattern
(17) Etch away copper over the resistor pattern using appropriate etchants
(18) Strip photoresist.
(19) Carry out inspection and test by resistance measurement.

After this, the result may be further laminated with other PCB layers.

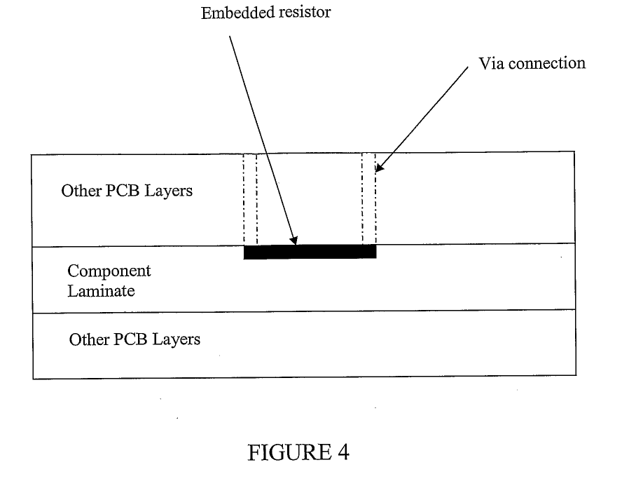

FIG. 4 shows a sectional view of the resistor embedded in the PCB with electrical connections made by vertical vias in the material.

The finished resistor is embedded in the PCB using standard techniques. Tiny holes in the PCB, called vias, are used to make electrical connection to the resistor in the usual way. The resistor is now in place to be trimmed using the trimmable resistor techniques. The algorithm developed for cavity trimming will be adapted to the problem, whereby a series of electrical pulses of variable amplitude, width and spacing are applied to the heating resistor. The amplitude is determined by the power density needed to heat the heating and functional resistors to 600° C. This value can be roughly estimated by extrapolating the Ohmega-ply data. As stated previously, infra red measurements have shown that for the smallest Ohmega-Ply resistors studied (0.031×0.031 inches square, area about 0.7 mm²) a temperature rise of 160° C. was obtained for a dissipated power of about 120 mW, corresponding to a power density of 2×10⁻⁴ mW/micron². A linear variation of temperature rise with dissipated power was observed up to that temperature. Extrapolating for a temperature rise of 600° C. leads to an estimated power density required of about 10⁻³ mW/micron², which is the same order of magnitude as that required for the trimmable resistor.

It is clear that even with pulse heating there is the obvious possibility that the polymer material adjacent to the resistors will be damaged, perhaps vaporized. From a thermal point of view this effect is beneficial as it will greatly improve the thermal isolation. From a mechanical point of view this raises the possibility of a weakening of the supporting polymer material around the resistors, perhaps even the formation of a cavity. It is known by practitioners of micro-electro-mechanical (MEMS) systems that the basic remaining poly/glass structure is self-supporting even in the limit of being surrounded by a cavity, so that the structure will be stable even in the most adverse scenario.

Indeed, the polymer material (or other substrate material), adjacent to the resistors may be suitable for intentional creation of a cavity within its bulk by heating to an elevated temperature (for example 250 C or above). There are several reactions that may occur when the substrate material is burned away. The reaction products of the burning could stay as a gas, potentially deforming the overall shape of the bulk substrate material. The reaction products of the burning could be absorbed into the substrate material, causing little or no deformation of the overall outer shape of the substrate material. A portion of the substrate material could undergo a phase change resulting in a higher density than the remaining solid portion and thus simply retract. Since the trimmable component contains a heating element, suitable to heat itself and its immediate surroundings, this heater may “burn” the cavity within the substrate material. This “burning” may involve a chemical reaction or phase transition within the substrate material, initiated by the heat from the heater. This may involve the creation of gaseous and solid reaction products in the cavity, which may or may not be absorbed into the substrate material.

Thus, in some cases, the creation of the cavity may generate a change (increase or decrease) in pressure or volume, which may be accommodated by mechanical changes in (e.g. expansion, retraction, stretching) of the surrounding material. Furthermore, the heat may result in direct modification of the structural properties of the solid surrounding the created cavity, such as shrinking or expanding, or stiffening. Such changes in properties may or may not compensate for any additional pressure or volume generated by the cavity reaction. Therefore, depending on the composition of the surrounding layers, gas pressure may be generated in the cavity either lower or higher than the surrounding ambient gas pressure, which can be important for certain applications. By using more complex materials as a substrate layers, certain advantages can be realized. For example, if a porous material (containing pre-formed micro-voids or nano-voids within its bulk) were used, this could facilitate the burning of the cavity without any macroscopic deformation or straining of the surrounding layers. In this case, reaction products of the burning would more easily dissipate among adjacent voids in unburned portions of the layer. This could be implemented by forming a polymer or an adhesive substance (e.g. epoxy), in a porous (or foamed) state, prior to or during deposition. Note also that there can be several heaters in close proximity embedded in the PCB. In this case, one could use the several heaters to create a common cavity in which a plurality of trimmable components could reside (and interact, if necessary). This could be done by creating separate cavities by separate heating events, in such a way that the cavities overlap creating a single cavity, or it could be done by simultaneously heating several heaters.

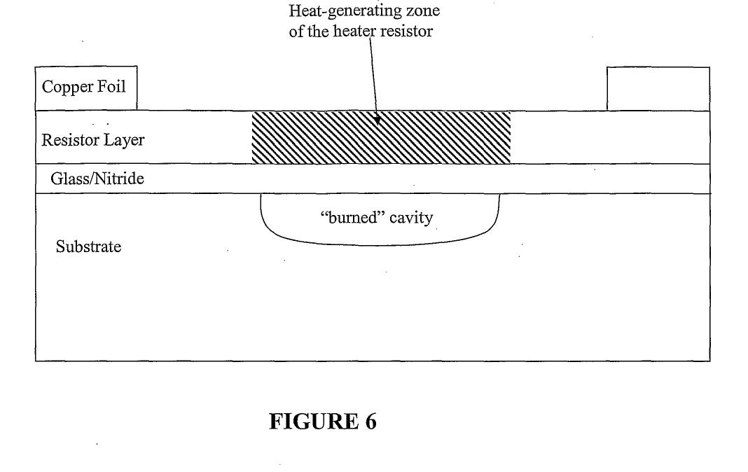

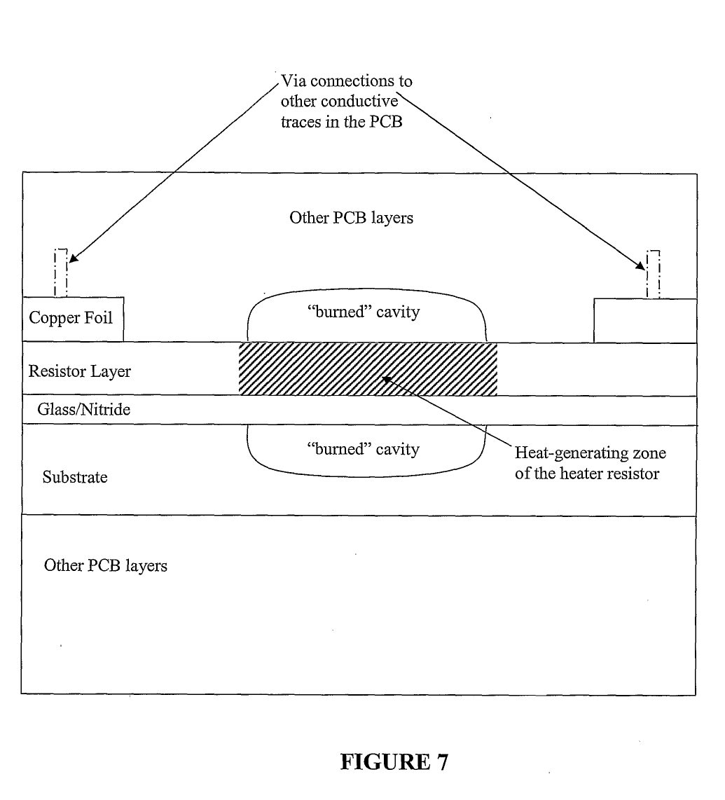

FIGS. 6 and 7 illustrate the cross section of the component laminate after the cavity has been burned. There may be cavities burned above and below the component, or only one of the two.

As described above, the present invention provides heating and functional resistors in the form of a stable structure embedded in a highly insulating medium, which allows raising the temperature of the two by use of the heating resistor in a controlled fashion in order to adjust the resistance value of the functional resistor by known and proven techniques. The method is advantageous in that it permits precision adjustment of embedded passive resistors after packaging, something that is not attainable with present techniques of mechanical trim pots or laser trimming.

A further advantage of the invention is that all of the techniques developed for the trimmable resistor in Silicon technology can be applied to the case of embedded passive resistors. In particular, the temperature coefficient of resistance (TCR) trimming and thermally stable voltage dividers can be realized for the embedded passives.

Although the preferred embodiment of the present invention have been disclosed for illustrative purposes, those skilled in the art will recognize that various modifications are possible and that the same principle can be used for any thermally mutable material, without departing from the scope and spirit of the invention as it is disclosed in the accompanying claims.

Another embodiment of the present invention is to apply directly the approach used in (Ross, Young, The Display search Monitor of America, Aug. 15, 2001, page 11) in the manufacture of Ultra Low temperature (ULTPS) TFTs on thin plastic substrates using the same sputtering technology at 100° C. In this case the process sequence is altered in that the nitride must be deposited first, then the poly and finally the copper needed to make the circuit connections will be deposited on the poly. Omitting the lithography steps, which are the same as above, but modified in an obvious way to those skilled in the art. The process sequence now becomes:

Deposit a 1-2 micron thick nitride film on a 10 micron Kapton™ film by sputtering as described previously.

Deposit a 1 micron poly film on the nitride by sputtering as described above.

Anneal the poly by standard ELA step.

Deposit a 10 micron film of copper by sputtering in the same chamber, using a pure copper target and methods standard for those skilled in the art.

Laminate the Kapton™ side of the multi layer structure to the chosen dielectric to form the desired laminate in preparation for the lithography steps.

Embedded passive components most typically are resistors or capacitors. While much of this text addresses thermally-trimmable embedded resistors, thermally-trimmable embedded capacitors are also possible. The most common capacitor design is in a parallel-plate configuration, with two sheets of conductor sandwiching a dielectric layer. The capacitor plates could be made of highly conductive material such as copper, or made from the same resistive material as used for trimmable resistors, as long as the sheet resistance was not too high. The dielectric could be provided by a thin layer of deposited glass or nitride, as described herein. It is known that the dielectric constant of silicon dioxide may be changed by high temperature annealing, and that deposited oxides may change their density (and hence dielectric constant) significantly by high-temperature annealing after deposition. Therefore, by placing a heater (as described herein) in close proximity to (above, below, or beside) the capacitor dielectric, one may apply heat to anneal the dielectric material, and thus change the capacitance

The embodiment(s) of the invention described above is(are) intended to be exemplary only. The scope of the invention is therefore intended to be limited solely by the scope of the appended claims.

1. A printed circuit board having at least one embedded thermally trimmable component comprising:
a substrate layer to provide physical support for said board;
a refractory insulating material on said substrate layer to provide at least one of mechanical support and chemical passivations for said thermally trimmable component;
a layer of thermally mutable material on said insulator material to form said thermally trimmable component; and
a conducting layer on said thermally mutable material to serve for electrical connections of said printed circuit board.

2. A printed circuit board as claimed in claim 1, wherein said substrate layer is an intermediate layer of a multi-layered board.

3. A printed circuit board as claimed in claim 1, wherein said conducting layer is copper foil.

4. A printed circuit board as claimed in claim 1, wherein said insulator material is glass.

5. A printed circuit board as claimed in claim 1, wherein said insulator material is plastic.

6. A printed circuit board as claimed in claim 1, wherein said substrate layer is Kapton™.

7. A printed circuit board as claimed in claim 1, wherein said layer of thermally mutable material is polysilicon.

8. A printed circuit board as claimed in claim 1, further comprising a second layer of said refractory insulator material on a second side of said thermally mutable material.

9. A printed circuit board as claimed in claim 1, wherein said component is a resistor.

10. A method of trimming a thermally trimmable component embedded into a printed circuit board, the method comprising:
embedding at least one layer of thermally mutable material into said board;
forming said thermally trimmable component from said thermally mutable material;
populating at least a portion of said board with additional circuit components and connecting said thermally trimmable component to said additional circuit components; and
subjecting said thermally trimmable component to a series of heat pulses to trim said thermally trimmable component.

11. A method as claimed in claim 10, wherein said forming said thermally trimmable component comprises forming a functional resistor and a heating resistor from said thermally mutable material, and said subjecting comprises subjecting said heating resistor to said heat pulses to trim said functional resistor.

12. A method as claimed in claim 10, wherein said embedding at least one layer comprises embedding two layers, wherein a first layer is for a functional resistor and a second layer is for a heating resistor and said subjecting comprises subjecting said heating resistor to said heat pulses to trim said functional resistor.

13. A method as claimed in claim 10, wherein said embedding at least one layer comprises:
depositing said at least one layer of thermally mutable material on a layer of conducting material;
coating said thermally mutable material with a layer of insulating material to act as a support medium for said thermally mutable material and a protective layer for a substrate during said trimming;
bonding said coating to said substrate to provide physical support for said board.

14. A method as claimed in claim 10, wherein said embedding at least one layer comprises:
depositing a layer of insulating material onto a substrate to act as a support medium for said thermally mutable material and a protective layer for said substrate during said trimming;
depositing said at least one layer of thermally mutable material on said insulating material; and
depositing a layer of conducting material onto said thermally mutable material to serve for electrical connections of said printed circuit board.

15. A method as claimed in claim 13, wherein said depositing said at least one layer of thermally mutable material comprises using a sputtering technique.

16. A method as claimed in claim 14, wherein said depositing a layer of insulating material comprises using a sputtering technique.

17. A method as claimed in claim 14, wherein said depositing a layer of conducting material comprises using a sputtering technique.

18. A method as claimed in claim 10, wherein said subjecting comprises providing a plurality of electrical pulses and measuring a value of said thermally trimmable component in between each of said plurality of electrical pulses to determine whether a target value has been obtained.

19. A method as claimed in claim 10, wherein said subjecting comprises providing dynamically-shaped electrical pulses to achieve substantially constant temperature as a function of time during a trimming pulse.

20. A method as claimed in claim 10, wherein said forming said thermally trimmable component comprises forming a thermally trimmable resistor.

21. A method for producing a printed circuit board with at least one embedded thermally trimmable component, the method comprising:
embedding at least one layer of thermally mutable material into said board and forming said thermally trimmable component from said thermally mutable material;
providing a heating element capable of heating itself and its immediate surroundings;
passing an electric current through said heating element to generate a heat source to burn away a portion of a material close to said thermally mutable component at least one of above and below said thermally mutable component to provide a cavity for thermal isolation of said thermally trimmable component.

22. A method as claimed in claim 21, wherein said forming said thermally trimmable component comprises forming a functional resistor and a heating resistor from said thermally mutable material, and said heating resistor is said heating element.

23. A method as claimed in claim 21, wherein said embedding at least one layer comprises embedding two layers, wherein a first layer is for a functional resistor and a second layer is for a heating resistor, and said heating resistor is said heating element.

24. A method as claimed in claim 21, wherein said embedding at least one layer comprises:
depositing said at least one layer of thermally mutable material on a layer of conducting material;
coating said thermally mutable material with a layer of insulating material to provide at least one of mechanical support and chemical passivation for said thermally trimmable component;
bonding said coating to said substrate to provide physical support for said board.

25. A method as claimed in claim 21, wherein said embedding at least one layer comprises:
depositing a layer of insulating material onto a substrate to provide at least one of mechanical support and chemical passivation for said thermally trimmable component;
depositing said at least one layer of thermally mutable material on said insulating material; and
depositing a layer of conducting material onto said thermally mutable material to serve for electrical connections of said printed circuit board.

26. A method as claimed in claim 24, wherein said depositing said at least one layer of thermally mutable material comprises using a sputtering technique.

27. A method as claimed in claim 25, wherein said depositing a layer of insulating material comprises using a sputtering technique.

28. A method as claimed in claim 25, wherein said depositing a layer of conducting material comprises using a sputtering technique.

29. A method as claimed in claim 21, wherein said passing an electric current through said heating element comprises providing a plurality of electrical pulses and measuring a value of said thermally mutable component in between each of said plurality of electrical pulses to determine whether a target value has been obtained.

30. A method as claimed claim 21, wherein said passing an electric current through said heating element comprises providing dynamically-shaped electrical pulses to achieve substantially constant temperature as a function of time during a trimming pulse.

31. A system for producing a printed circuit board with at least one embedded thermally trimmable component, said system comprising:
a stack of layers comprising at least a substrate, said thermally trimmable component, a heating element and a conducting layer for electrical connections of said printed circuit board; and
heating circuitry for passing an electric current through said heating element to generate a heat source to burn away a portion of a material at least one of above and below said thermally mutable component to provide a cavity for thermal isolation of said thermally trimmable component.

32. A system as claimed in claim 31, wherein said stack of layers comprises a refractory insulating material on said substrate to provide at least one of mechanical support and chemical passivation for said thermally trimmable component.

33. A system as claimed in claim 31, wherein said portion of a material burned away is a portion of said substrate.
